(19) United States
(12) Patent Application Publication
(10) Pub. No.: US 2023/0374648 A1
(43) Pub. Date: Nov. 23, 2023

(54) MASK AND MASK ASSEMBLY

(71) Applicant: Hefei Visionox Technology Co., Ltd., Hefei (CN)

(72) Inventors: Gongzheng ZANG, Hefei (CN); Wenxing LI, Hefei (CN); Weili LI, Hefei (CN); Bing HAN, Hefei (CN); Jishuai ZHANG, Hefei (CN); Yue QIU, Hefei (CN)

(73) Assignee: Hefei Visionox Technology Co., Ltd., Hefei (CN)

(21) Appl. No.: 18/362,160

(22) Filed: Jul. 31, 2023

Related U.S. Application Data
(63) Continuation of application No. PCT/CN2022/108576, filed on Jul. 28, 2022.

(30) Foreign Application Priority Data
Nov. 29, 2021 (CN) 202111436501.0

(51) Int. Cl. C23C 14/04

(52) U.S. Cl. CPC C23C 14/042

(57) ABSTRACT

A mask and a mask assembly. The mask includes an evaporation region and a peripheral region. The evaporation region includes at least one evaporation opening. The peripheral region includes a solid region arranged around the evaporation region. The solid region includes a stress-relieving portion. The stress-relieving portion is arranged around the evaporation region and is distributed in a circumferential direction.

### CROSS REFERENCE TO RELATED APPLICATION

The present application is a continuation application of International Application No. PCT/CN2022/108576, filed on Jul. 28, 2022, which claims priority to Chinese Patent Application No. 202111436501.0, filed on Nov. 29, 2021, titled “MASK AND MASK ASSEMBLY”, both of which are hereby incorporated by reference in their entireties.

### TECHNICAL FIELD

The present application relates to the technical field of display, and in particular to a mask and a mask assembly.

### BACKGROUND

An Organic Light Emitting Diode (OLED) display panel has the advantages of low driving voltage, active luminescence, wide viewing angle, high efficiency, fast response speed and the like, so that it can be increasingly widely used and become the mainstream technology of the display panel. During a manufacturing process of the OLED display panel, it is necessary to apply a vacuum evaporation technology to form a part of film layers in the display panel. In the vacuum evaporation technology, a mask is needed to control the position of the organic material used to form the film layers. The mask mainly includes a common Metal Mask (CMM) and a Fine Metal Mask (FMM). The CMM can be used for evaporating a common layer, and the FMM can be used for evaporating a light-emitting layer.

The Fine Metal Mask (FMM) may be a mesh structure, including a display region and a non-display area to meet the requirements of the functions of different regions of the display panel. The fine metal mask is prone to wrinkles during net-tensioning, and it is easy to appear that the fine metal mask cannot be absorbed and flattened by the magnetic field during evaporation, so as to affect the evaporation effect.

### SUMMARY

A mask and a mask assembly are provided by embodiments of the present application. The mask is not easy to produce wrinkles during net-tensioning, thereby improving the evaporation yield.

In a first aspect, the embodiments of the present application provide the mask, including:
an evaporation region, including at least one evaporation opening;
a peripheral region, including a solid region arranged around the evaporation region, in which the solid region includes a stress-relieving portion, and the stress-relieving portion is arranged around the evaporation region and is distributed in a circumferential direction.

In a second aspect, the embodiments of the present application provide the mask assembly, including the mask provided by the first aspect, further including a mask frame and a support bar fixed to the mask frame, in which the mask is arranged at a side of the support bar away from the mask frame and fixed with the mask frame.

Compared with the prior art, the mask provided by the embodiments of the present application includes the evaporation region and the peripheral region, the peripheral region includes the solid region arranged around the evaporation region, and the solid region includes the stress-relieving portion which is arranged around the evaporation region and is distributed in a circumferential direction. The stress-relieving portion can reduce a volume of a stress concentration part in the solid region. Since the stress-relieving portion is distributed around the evaporation region in a circumferential direction, so that a stress of the solid region can be evenly released. The stress-relieving portion can be formed in the peripheral region, so that a strain of the mask tends to be uniform during net-tensioning, and the mask can be not easy to produce wrinkles during net-tensioning, thereby improving an evaporation yield.

### BRIEF DESCRIPTION OF THE DRAWINGS

FIG. 1 shows a schematic structural view of a mask provided by an embodiment of the present application;

FIG. 2 shows an enlarged schematic view of region A in FIG. 1;

FIG. 3 shows a schematic structural view of a first mask provided by an embodiment of the present application;

FIG. 4 shows a schematic structural view of a second mask provided by an embodiment of the present application;

FIG. 5 shows a schematic structural view of a third mask provided by an embodiment of the present application;

FIG. 6 shows a schematic structural view of a fourth mask provided by an embodiment of the present application;

FIG. 7 shows a schematic structural view of a fifth mask provided by an embodiment of the present application;

FIG. 8 shows a schematic structural view of a sixth mask provided by an embodiment of the present application;

FIG. 9 shows a schematic structural view of a sixth mask provided by an embodiment of the present application; and

FIG. 10 shows a schematic structural view of a mask assembly provided by an embodiment of the present application.

### DETAILED DESCRIPTION

After research, the inventor finds that the reason why a fine metal mask is prone to wrinkles during net-tensioning is that: in the fine metal mask, a non-display region is arranged around the display region, and a volume ratio of a full-etched region in the display region is relatively large, a volume ratio of an unetched region in the non-display region is relatively large, and cross-sectional shapes of the display region and the non-display region are different, so that it makes a stress distribution at a junction place between the display region and the non-display region uneven. Therefore, during net-tensioning, the overall stress distribution of the fine metal mask is not uniform, and the local wrinkles are easy to occur, so that a part of the fine metal mask cannot be absorbed and flattened by a magnetic field during evaporation, and a net-tensioning effect will be affected. Based on the analysis of the above problems, the inventor proposes a mask and a mask assembly.

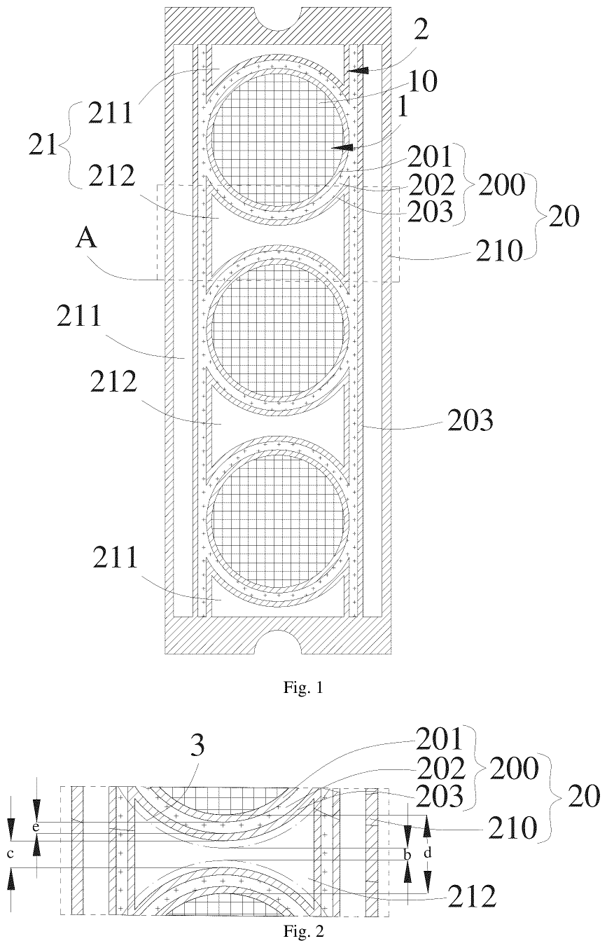

In order to better understand the present application, the mask and the mask assembly according to embodiments of the present application will be described in detail below with reference to FIG. 1 to FIG. 10.

Referring to FIG. 1, the embodiments of the present application provide the mask, including an evaporation region 1 and a peripheral region 2. The evaporation region 1 includes at least one evaporation opening 10; the peripheral region 2 includes a solid region 20 arranged around the evaporation region 1. A stress-relieving portion 21 may be formed on the solid region 20, and the stress-relieving portion 21 is arranged around the evaporation region 1 and is distributed in a circumferential direction.

The peripheral region 2 is a whole region of the mask except the vapor deposition region 1. The evaporation region 1 may include a plurality of precision evaporation openings, or include a general evaporation opening, which is not specifically limited in the present application.

The mask provided by the embodiments of the present application includes the evaporation region 1 and the peripheral region 2, the peripheral region 2 includes the solid region 20 arranged around the evaporation region 1, and the solid region 20 includes the stress-relieving portion 21 which is arranged around the evaporation region 1 and is distributed in a circumferential direction. The stress-relieving portion 21 can reduce a volume of a stress concentration part in the solid region 20. Since the stress-relieving portion 21 is distributed around the evaporation region 1 in the circumferential direction, so that a stress of the solid region 20 can be evenly released. The stress-relieving portion can be formed in the peripheral region 2, so that a strain of the mask tends to be uniform during net-tensioning, and the mask can be not easy to produce wrinkles during net-tensioning, thereby improving an evaporation yield.

In the feasible embodiments, as shown in FIG. 1, the solid region 20 includes a first shielding region 200 arranged at least partially around the evaporation region 1 and a second shielding region 210 extending in an outer peripheral direction of the peripheral region 2, and the first shielding region 200 is connected to a part region of the second shielding region 210.

In the feasible embodiments, the stress-relieving portion 21 includes a plurality of first stress-relieving holes 211 and/or a plurality of second stress-relieving holes 212, the plurality of first stress-relieving holes 211 are located between the first shielding region 200 and the second shielding region 210 in a row direction, and/or the plurality of the first stress-relieving holes 211 are located between the first shielding region 200 and the second shielding region 210 in a column direction. The plurality of second stress-relieving holes 212 are located within the first shielding region 200, and each of the first stress-relieving holes 211 and the second stress-relieving holes 212 penetrates through the solid region 20 in a thickness direction of the solid region 20.

In the above embodiments, the solid region 20 in the peripheral region 2 corresponds to the non-display region, so as to define a shape of the display region, that is, the evaporation region 1. The peripheral region 2 may include the solid region 20 for shielding an evaporation material. The solid region 20 may include the first shielding region 200 and the second shielding region 210. A part region of the first shielding region 200 may be connected with a part region of the second shielding region 210 so as to realize the overall support of the mask. Through the arrangement of the first stress-relieving holes 211 and/or the second stress-relieving holes 212, the volume of the solid region 20 in the peripheral region 2 can be reduced, that is, a volume of a region that can provide support in the peripheral region 2 can be reduced. Since a volume of a region that can provide support in the evaporation region 1 in the mask is much smaller than the volume of the region that can provide support in the peripheral region, the difference in shape between the peripheral region 2 and the evaporation region 1 can be reduced after reducing the volume of the solid region in the peripheral region, so that the difference in strain between the evaporation region 1 and the peripheral region 2 can be reduced. Therefore, the strains in the evaporation region 1 and the peripheral region 2 tend to be uniform, so that it can improve the overall strain uniformity of the mask, thereby reducing the generation of wrinkles during net-tensioning in the mask, and improving the evaporation yield.

In the feasible embodiments, as shown in FIG. 1, the first shielding region 200 includes a first shielding sub-region 201 arranged at least partially around the evaporation region 1, a second shielding sub-region 202 arranged at least partially around the first shielding sub-region 201, and a third shielding sub-region 203 arranged at least partially around the second shielding sub-region 202. The first shielding sub-region 201, the second shielding sub-region 202 and the third shielding sub-region 203 are sequentially distributed from the evaporation region 1 to the stress-relieving portion 21.

In the above embodiments, the first shielding region 200 includes the first shielding sub-region 201, the second shielding sub-region 202 and the third shielding sub-region 203. The first shielding sub-region 201 at least partially surrounds the evaporation region 1 to define the evaporation region 1. Parts or all of the first shielding sub-region 201, the second shielding sub-region 202 and the third shielding sub-region 203 can be connected to the second shielding region 210 to achieve integral support.

In a feasible embodiment, thicknesses of the first shielding sub-region 201, the second shielding sub-region 202 and the third shielding sub-region 203 may be the same, so as to facilitate manufacture.

In another feasible embodiment, the thickness of the first shielding sub-region 201 may be the same as the thickness of the third shielding sub-region 203, and the thickness of the second shielding sub-region 202 may be smaller than the thickness of the first shielding sub-region 201.

In the above embodiments, the first shielding sub-region 201 and the third shielding sub-region 203 are unetched regions, and the second shielding sub-region 202 is a partially-etched region. In other words, during a manufacturing process, the partially-etched region can be formed in a solid portion to form the second shielding sub-region 202, and the thickness of the second shielding sub-region 202 can be arranged to be smaller than the thickness of the first shielding sub-region 201 and the thickness of the third shielding sub-region 202, so as to reduce a volume of the solid portion and reduce the volume of the region that can provide support in the solid portion. Since the volume of the region that can provide support in the evaporation region 1 in the mask may be much smaller than the volume of the region that can provide support in the peripheral region 2, the difference in stress distribution between the peripheral region 2 and the evaporation region 1 can be reduced after reducing the volume of the solid region in the peripheral region 2, so that the strain in each region of the mask can tend to be uniform during the net-tensioning process. Therefore, the mask may be not easy to generate wrinkles during net-tensioning, the accuracy of the position of the evaporation material can be improved, and the evaporation yield can be improved.

The mask provided by the present application includes a plurality of evaporation regions 1 arranged in rows and columns. The arrangement of the evaporation regions 1 in the mask can be reasonably arranged according to an area of the mask and an area of each of the evaporation regions 1, which may be not particularly limited in the present application.

In a feasible embodiment, in an edge of each of the first stress-relieving holes 211 located between the first shielding region 200 and the second shielding region 210 in the row direction or the column direction, a shape of the edge facing the evaporation region 1 may match with a shape of an edge of the evaporation region 1, or a shape of each of the first stress-relieving holes 211 may be a rectangle. The second stress-relieving holes 212 may be formed within the third shielding sub-region 203, a shape of an edge of each of the second stress-relieving holes 212 facing the evaporation region 1 may match with a shape of an edge of the evaporation region 1, or a shape of each of the second stress-relieving holes 212 may be a rectangle.

In a feasible embodiment, in the edge of each of the first stress-relieving holes 211 located between the first shielding region 200 and the second shielding region 210 in the column direction, the shape of the edge facing the evaporation region 1 may match with the shape of an edge of the evaporation region 1.

In a specific embodiment, as shown in FIG. 1, at an upper end and an lower end in FIG. 1, in the edges of the two first stress-relieving holes 211 arranged in the column direction, the shapes of the edges facing the evaporation region 1 may match with the shapes of the edges of the evaporation regions 1; the shapes of the two first stress-relieving holes 211 located at a left end and a right end (i.e. distributed in the row direction) may be the rectangles.

In the above embodiments, the edge of the second shielding region 210 facing the evaporation region 1 is a straight line. In the edge of the first shielding region 200 at a side away from the evaporation region 1 in the column direction, the shape of at least part of the edge may match with the shape of the edge of the evaporation region 1. The first stress-relieving holes 211 can be formed between the first shielding region 200 and the second shielding region 210, so that the shape of the edge of part of the first stress-relieving holes 211 facing the evaporation region 1 can match with the shape of the edge of the evaporation region 1. When the shape of the evaporation region 1 may be a circle, a portion of the edge of the part of the first stress-relieving holes 211 facing the evaporation region 1 may be an arc shape, and the other portion may be a straight line shape.

The second stress-relieving holes 212 may be located within the first shielding region 200. The mask includes the evaporation region 1 having 1 column and 3 rows. The evaporation region 1 may be located in the edges of the second stress-relieving holes 212 between adjacent evaporation regions 1 in the column direction, and the shape of the part of the edges facing the evaporation region 1 may match with the shape of the edge of the evaporation region 1, so that the ratio of the second stress-relieving holes 212 in the peripheral region can increase, the volume of the solid portion in the peripheral region can be further reduced, and the volume of the portions that can provide support in the peripheral region and the evaporation region can be reduced. Therefore, the strain uniformity of the mask can be further improved.

As shown in FIG. 1 and FIG. 2, when the evaporation region 1 is circular, each of the second stress-relieving holes 212 located between two adjacent evaporation regions 1 may include an arc-shaped side edge matching with one of the evaporation regions 1 and an arc-shaped side edge matching with the other of the evaporation regions 1. In the column direction, a minimum distance between two screen bodies respectively corresponding to two adjacent evaporation regions 1 is b, and a minimum width of each of the second stress-relieving holes 212 located between the two adjacent evaporation regions 1 is c, herein b/2<c<b. In the column direction, a minimum distance between adjacent evaporation regions 1 is d, and a minimum width of the second shielding sub-region 202 is e, herein, 0<e<(d−b)/2.

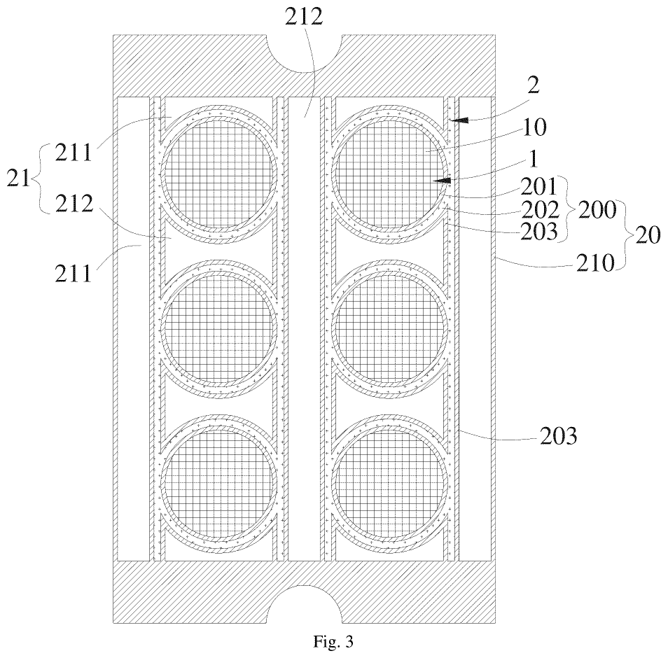

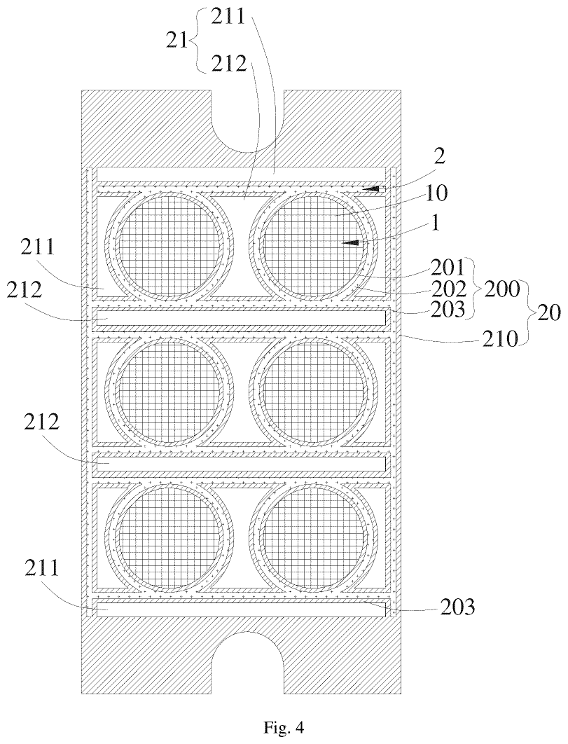

As shown in FIG. 3, when the mask includes the evaporation region 12 having columns and 3 rows, in the edge of each of the first stress-relieving holes 211 located between the first shielding region 200 and the second shielding region 210 in the column direction, the shape of the edge facing the evaporation region 1 may match with the shape of the edge of the evaporation region 1. The shape of each of the first stress-relieving holes located between the first shielding region 200 and the second shielding region 210 in the row direction may be a rectangle. The shape of each of the second stress-relieving holes 212 located between two adjacent columns may be a rectangle. The rectangle extends in the column direction, so that it can better reduce the volume of the peripheral region 2 between two adjacent columns. In the edge of each of the second stress-relieving holes 212 located between the two adjacent evaporation regions 1 in the column direction, the shape of the edge facing the evaporation region 1 may match with the shape of the edge of the evaporation region 1, so that the ratio of the second stress-relieving holes 212 in the peripheral region can increase, the volume of the solid portion in the peripheral region 2 can be further reduced, and the volume of the portions that can provide support in the peripheral region 2 and the evaporation region 1 can be reduced. Therefore, the strain uniformity of the mask can be further improved.

In another specific embodiment, in the edge of each of the first stress-relieving holes 211 located between the first shielding region 200 and the second shielding region 210 in the row direction, the shape of the edge facing the evaporation region 1 may match with the shape of the edge of the evaporation region 1.

As shown in FIG. 4, at a left side and a right side in FIG. 4, in the edge of each of the first stress-relieving holes 211 arranged in the row direction, the shape of the edge facing the evaporation region 1 may match with the shape of the edge of the evaporation region 1, so that the ratio of the second stress-relieving holes 212 in the peripheral region can increase, the volume of the solid portion in the peripheral region 2 can be further reduced, and the volume of the portions that can provide support in the peripheral region 2 and the evaporation region 1 can be reduced. Therefore, the strain uniformity of the mask can be further improved. The shapes of the two first stress-relieving holes 211 located at an upper side and a lower side (i.e. distributed in the column direction) may be the rectangles.

In the above embodiments, the edge of the second shielding region 210 facing the evaporation region 1 is the straight line. In the edge of the first shielding region 200 at a side away from the evaporation region 1 in the row direction, the shape of at least part of the edge may match with the shape of the edge of the evaporation region 1. The first stress-relieving holes 211 can be formed between the first shielding region 200 and the second shielding region 210, so that the shape of the edge of part of the first stress-relieving holes 211 facing the evaporation region 1 can match with the shape of the edge of the evaporation region 1. When the shape of the evaporation region 1 may be the circle, the portion of the edge of the part of the first stress-relieving holes 211 facing the evaporation region 1 may be the arc shape, and the other portion may be the straight line shape.

The second stress-relieving holes 212 may be located within the first shielding region 200. In the edge of each of the second stress-relieving holes 212 located between the evaporation regions 1 arranged in the row direction, the shape of the edge facing the evaporation region 1 may match with the shape of the edge of the evaporation region 1, so that the ratio of the second stress-relieving holes 212 in the peripheral region can increase, the volume of the solid portion in the peripheral region 2 can be further reduced, and the volume of the portions that can provide support in the peripheral region 2 and the evaporation region 1 can be reduced. Therefore, the strain uniformity of the mask can be further improved. The shape of each of the second stress-relieving holes 212 located between the two adjacent rows (i.e. distributed in the column direction) may be the rectangle, so that the volume of the solid portion in the peripheral region can be further reduced.

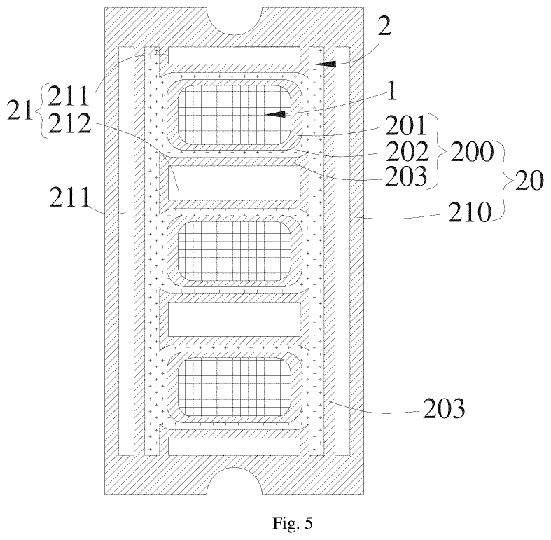

In a feasible embodiment, as shown in FIG. 3, the shape of the evaporation region 1 may be the circle, or the shape of the evaporation region 1 may be a rectangle with rounded corners. As shown in FIG. 5, the shape of the evaporation region 1 can be arranged according to the shape of the display region of the screen body during practical application, which is not particularly limited in the present application.

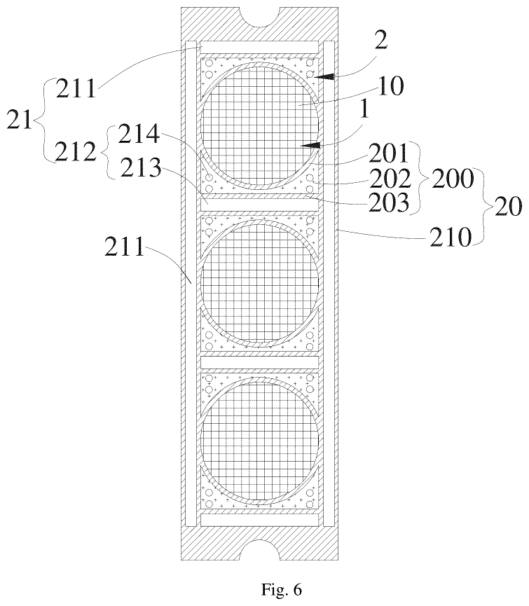

In a feasible embodiment, as shown in FIG. 6, each of the second stress-relieving holes 212 includes a first sub-hole 213 and a second sub-hole 214, the first sub-hole 213 may be located within the third shielding sub-region 203 and located between adjacent evaporation regions 1, and the second sub-hole 214 is located within the second shielding sub-region 202.

In a feasible embodiment, each of shapes of the first stress-relieving holes 211 and the first sub-hole 213 may be the rectangle, and a shape of the second sub-hole 214 may be the circle or an ellipse.

In the above embodiments, the shape of the edge of the second shielding region 210 facing the evaporation region 1 may be the rectangle. The edge of the first shielding region 200 facing away from the evaporation region 1 may be parallel to the edge of the second shielding region 210 facing the evaporation region 1. The shape of the edge at a side of the second shielding sub-region 202 facing the evaporation region 1 may match with the shape of the edge of the evaporation region 1. The shape of edge at the side of the second shielding sub-region 202 facing away from the evaporation region 1 may be the straight line. Each of the first stress-relieving holes 211 may be a rectangular hole formed between the first shielding region 200 and the second shielding region 210. Each of the second stress-relieving holes 212 includes the first sub-hole 213 and the second sub-hole 214. The first sub-hole 213 may be a rectangular hole formed within the third shielding sub-region 203 and located between adjacent evaporation regions 1. The second sub-hole 214 may be a circular hole or an elliptical hole formed in the second shielding sub-region 202.

In a feasible embodiment, a plurality of the second sub-holes 214 can be arranged and evenly distributed within the second shielding sub-region 202, so that the volume of a portion that can provide support in the second shielding sub-region can be reduced, the difference in volume between the evaporation region 1 and a portion that can provide support in the peripheral region can be reduced, and the stress in each region in the mask tends to be uniform.

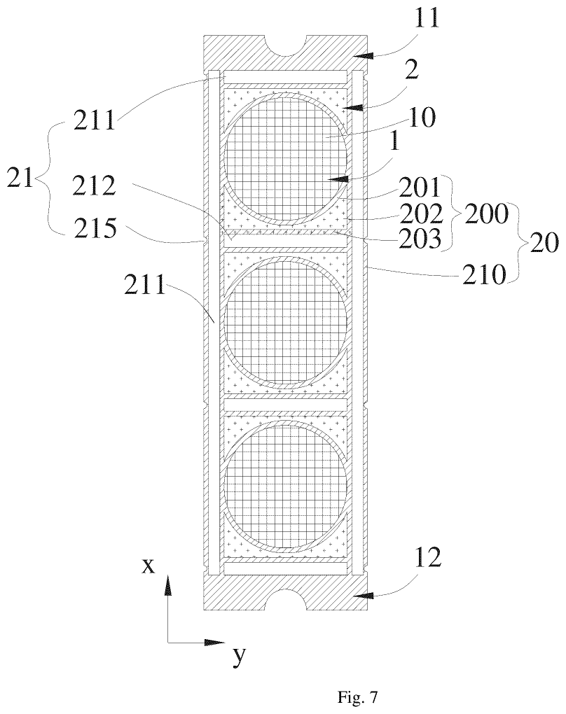

In a feasible embodiment, as shown in FIG. 7, the stress-relieving portion 21 further includes a plurality of third stress-relieving holes 215, the mask includes a first end 11 and a second end 12 for net-tensioning, the first end 11 and the second end 12 can be arranged in a first direction x, the third stress-relieving holes 215 can be formed in regions of the second shielding region 210. The third stress-relieving holes 215 can be formed in the second shielding region 210 at a side away from the evaporation region 1. Along the first direction x, the third stress-relieving holes 215 are disposed away from a center of the evaporation regions 1. It means that, along a second direction y perpendicular to the first direction x, an orthographic projection of the evaporation region 1 could not cover, or just have an edge thereof partially cover an orthographic projections of the third stress-relieving holes 215. In the embodiment, in the first direction x, the third stress-relieving holes 215 are respectively located between every two adjacent evaporation regions 1.

In a feasible embodiment, the third stress-relieving holes 215 can be distributed along the edge of the second shielding region 210, and a cross-sectional shape of each of the third stress-relieving holes 215 may be a semicircle or a semi-ellipse. A maximum size of each of the third stress-relieving holes 215 in the first direction x may be 1.6 mm-3.0 mm. When the shape of each of the third stress-relieving holes 215 is the semicircle, an outer peripheral edge of the peripheral region 2 may coincide with a diameter of the semicircle. When the shape of each of the third stress-relieving holes 215 is the semi-ellipse, the outer peripheral edge of the peripheral region 2 may coincide with a major axis of the semi-ellipse.

In a feasible embodiment, the mask needs to be used in conjunction with a support bar 4. The support bar 4 can be arranged opposite a region between the adjacent evaporation regions 1, and the orthographic projections of the third stress-relieving holes 215 on the support bar 4 can be located within the support bar 4.

In a feasible embodiment, as shown in FIG. 7, the shape of the edge of the second shielding region 210 facing the evaporation region 1 may be the rectangle. The edge of the first shielding region 200 facing away from the evaporation region 1 may be parallel to the edge of the second shielding region 210 facing the evaporation region 1. The first stress-relieving holes 211 can be formed between the first shielding region 200 and the second shielding region 210 and may be the rectangle in shape. The second stress-relieving holes 212 can be formed within the third shielding sub-region 203 and may be the rectangle in shape. The third stress-relieving holes 215 can be formed in the second shielding region 210 and correspond to the second stress-relieving holes 212 and the first stress-relieving holes 211 close to the first end and the second end.

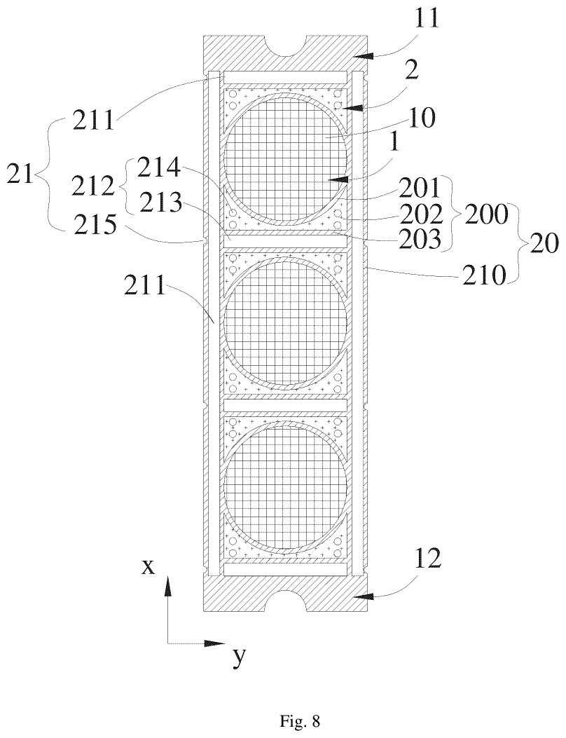

In another feasible embodiment, as shown in FIG. 8, the shape of the edge of the second shielding region 210 facing the evaporation region 1 may be the rectangle. The edge of the first shielding region 200 facing away from the evaporation region 1 may be parallel to the edge of the second shielding region 210 facing the evaporation region 1. The shape of the edge at a side of the second shielding sub-region 202 facing the evaporation region 1 may match with the shape of the edge of the evaporation region 1. The shape of edge at the side of the second shielding sub-region 202 facing away from the evaporation region 1 may be the straight line. Each of the first stress-relieving holes 211 may be a rectangular hole formed between the first shielding region 200 and the second shielding region 210. Each of the second stress-relieving holes 212 includes the first sub-hole 213 and the second sub-hole 214. The first sub-hole 213 may be a rectangular hole formed within the third shielding sub-region 203 and located between adjacent evaporation regions 1. The second sub-hole 214 may be a circular hole or an elliptical hole formed in the second shielding sub-region 202. The third stress-relieving holes 215 can be formed in the second shielding region 210 and arranged to correspond to the second stress-relieving holes 212 and the first stress-relieving holes 211 close to the first end and the second end.

In the above embodiments, the third stress-relieving holes 215 can be provided in the second shielding region 210, so that the volume of a portion that can provide support in the second shielding region 210 can be reduced, and the difference in stress distribution between the second shielding region 210 and the evaporation region can be reduced, so as to make a stress region of the whole mask uniform.

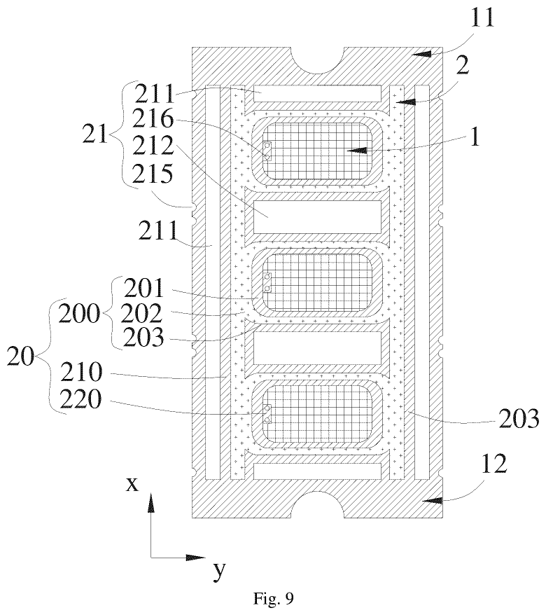

In a feasible embodiment, as shown in FIG. 9, the solid region 20 further includes a third shielding region 220 extending from the first shielding region 200 to the evaporation region 1, and the third shielding region 220 can be used to define a notch region (that is, a notch for placing the photosensitive module and the like in the non-display region of the special-shaped screen, i.e. notch region) in the special-shaped screen such as a notch screen. The stress-relieving portion 21 further includes a fourth stress-relieving hole 216 formed in the third shielding region 220. The fourth stress-relieving hole 216 may be a through hole penetrating through the third shielding region 220 in a thickness direction of the third shielding region 220, or a blind hole with a depth smaller than a thickness of the third shielding region 220 in the thickness direction of the third shielding region 220. In some embodiments, in the case that the fourth stress-relieving hole 216 is the blind hole, the depth of the blind hole is greater than a half of the thickness of the third shielding region 220.

In a feasible embodiment, the fourth stress-relieving hole 216 may be a round hole, and a radius of the fourth stress-relieving hole 216 can be 0.1 mm-0.5 mm.

In the above embodiments, the fourth stress-relieving hole 216 can release the stress at a stress concentration position in the third shielding region 220, so that the difference in cross-sectional shape between the third shielding region 220 and the evaporation region 1 can be reduced, the overall strain uniformity of the evaporation region 1 can be improved. Therefore, the mask may be not easy to produce wrinkles during net-tensioning, and the evaporation yield can be improved.

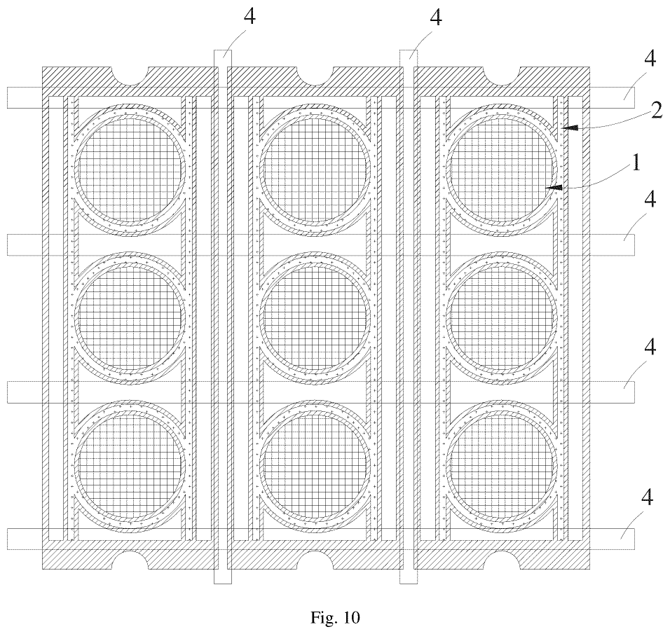

As shown in FIG. 10, the present application further provides a mask assembly, including the mask provided by any one of the above embodiments, further including a mask frame and a support bar fixed to the mask frame. The mask can be arranged at a side of the support bar away from the mask frame and fixed with the mask frame.

During the mask assembly working, an evaporation face of the mask can face an evaporation source, a glass of the mask can face a substrate, and the support bar can be located on the evaporation face of the mask, so as to prevent the mask from sagging during the evaporation process, and further reduce the wrinkle phenomenon of the mask during the net-tensioning process.

In accordance with the embodiments of the present application described above, these embodiments do not describe all details in detail, nor do they limit the present invention to only the specific embodiments described above. Obviously, many modifications and variations are possible in light of the above description. The description selects and specifically describes these embodiments in order to better explain the principles and practical applications of the present application, so that those skilled in the art can make good use of the present application and the modifications based on the present application. The present application is to be limited only by the claims, along with their full scope and equivalents.

What is claimed is:

1. A mask, comprising:
an evaporation region, comprising at least one evaporation opening; and
a peripheral region, comprising a solid region arranged around the evaporation region, wherein the solid region comprises a stress-relieving portion, and the stress-relieving portion is arranged around the evaporation region and distributed in a circumferential direction.

2. The mask according to claim 1, wherein the evaporation region comprises a plurality of precision evaporation openings, or comprises a general evaporation opening, and a shape of the evaporation region is a circle or a rectangle with rounded corners.

3. The mask according to claim 1, wherein the mask comprises a plurality of evaporation regions, and the plurality of evaporation regions are arranged in rows or columns.

4. The mask according to claim 3, wherein the solid region comprises a first shielding region arranged at least partially around the evaporation regions and a second shielding region extending in an outer peripheral direction of the peripheral region, and the first shielding region is connected to a part region of the second shielding region;
the stress-relieving portion comprises a plurality of first stress-relieving holes and a plurality of second stress-relieving holes, the plurality of first stress-relieving holes are located between the first shielding region and the second shielding region in a row direction, and the plurality of the first stress-relieving holes are located between the first shielding region and the second shielding region in a column direction;
the plurality of second stress-relieving holes are located within the first shielding region, and both of the first stress-relieving holes and the second stress-relieving holes penetrate through the solid region in a thickness direction of the solid region.

5. The mask according to claim 4, wherein the first shielding region comprises a first shielding sub-region arranged at least partially around the evaporation region, a second shielding sub-region arranged at least partially around the first shielding sub-region, and a third shielding sub-region arranged at least partially around the second shielding sub-region, and the first shielding sub-region, the second shielding sub-region and the third shielding sub-region are sequentially distributed from the evaporation region to the stress-relieving portion;
thicknesses of the first shielding sub-region, the second shielding sub-region and the third shielding sub-region are the same, or, thicknesses of the first shielding sub-region and the third shielding sub-region are the same and a thickness of the second shielding sub-region is smaller than the thickness of the first shielding sub-region.

6. The mask according to claim 5, wherein part or all of the first shielding sub-region, the second shielding sub-region and the third shielding sub-region are connected to the second shielding region.

7. The mask according to claim 5, wherein the first shielding sub-region and the third shielding sub-region are unetched regions, and the second shielding sub-region is a partially-etched region.

8. The mask according to claim 5, wherein in an edge of each of the first stress-relieving holes located between the first shielding region and the second shielding region in the row direction or the column direction, a shape of a part of the edge facing the evaporation regions matches with shapes of edges of the evaporation regions, or a shape of each of the first stress-relieving holes is a rectangle.

9. The mask according to claim 5, wherein the second stress-relieving holes are formed within the third shielding sub-region, a shape of a part of an edge of each of the second stress-relieving holes facing the evaporation regions matches with shapes of edges of the evaporation regions, or a shape of each of the second stress-relieving holes is a rectangle.

10. The mask according to claim 5, wherein each of the second stress-relieving holes comprises a first sub-hole and a second sub-hole, the first sub-hole is located within the third shielding sub-region and located between adjacent evaporation regions, and the second sub-hole is located within the second shielding sub-region.

11. The mask according to claim 10, wherein each of the first stress-relieving holes and the first sub-hole is in a shape of a rectangle, and the second sub-hole is in a shape of a circle or an ellipse.

12. The mask according to claim 10, wherein a plurality of second sub-holes are arranged and evenly distributed within the second shielding sub-region.

13. The mask according to claim 4, wherein the stress-relieving portion further comprises a plurality of third stress-relieving holes, the mask comprises a first end and a second end for net-tensioning, the first end and the second end are arranged in a first direction, the third stress-relieving holes are formed in regions of the second shielding region.

14. The mask according to claim 13, wherein the third stress-relieving holes are formed in the second shielding region at a side away from the evaporation region, and along a second direction perpendicular to the first direction, orthographic projection of the evaporation region not cover, or having an edge thereof partially cover an orthographic projections of the third stress-relieving holes.

15. The mask according to claim 13, wherein a cross-section of each of the third stress-relieving holes is in a shape of a semicircle, and an outer peripheral edge of the peripheral region coincides with a diameter of the semicircle.

16. The mask according to claim 13, wherein a cross-section of each of the third stress-relieving holes is in a shape of a semi-ellipse, and an outer peripheral edge of the peripheral region coincides with a major axis of the semi-ellipse.

17. The mask according to claim 4, wherein the solid region further comprises a third shielding region extending from the first shielding region to the evaporation region, and the stress-relieving portion further comprises a fourth stress-relieving hole formed in the third shielding region.

18. The mask according to claim 17, wherein the fourth stress-relieving hole is a through hole penetrating through the third shielding region in a thickness direction of the third shielding region, or is a blind hole with a depth smaller than a thickness of the third shielding region in a thickness direction of the third shielding region.

19. The mask according to claim 17, wherein the fourth stress-relieving hole is a round hole, and a radius of the fourth stress-relieving hole is 0.1 mm-0.5 mm.

20. A mask assembly, comprising at least one mask according to claim 1, further comprising a mask frame and a support bar fixed to the mask frame, wherein the mask is arranged at a side of the support bar away from the mask frame and fixed with the mask frame.
